(19) United States
(12) Patent Application Publication
(10) Pub. No.: US 2024/0145353 A1
(43) Pub. Date: May 2, 2024

(54) SEMICONDUCTOR MODULE, METHOD FOR MANUFACTURING SEMICONDUCTOR MODULE, SEMICONDUCTOR DEVICE, AND VEHICLE

(71) Applicant: FUJI ELECTRIC CO., LTD., Kawasaki-shi (JP)

(72) Inventors: Tsubasa NAKAMURA, Kawasaki-shi (JP); Daiki YOSHIDA, Kawasaki-shi (JP); Nobuhiro HIGASHI, Kawasaki-shi (JP)

(73) Assignee: FUJI ELECTRIC CO., LTD., Kawasaki-shi (JP)

(21) Appl. No.: 18/456,647

(22) Filed: Aug. 28, 2023

(30) Foreign Application Priority Data
Oct. 27, 2022 (JP) 2022-171969

(51) Int. Cl. H01L 23/495; H01L 23/00

(52) U.S. Cl. CPC H01L 23/49551; H01L 24/37; H01L 24/40; H01L 24/84; H01L 2224/37013; H01L 2224/40227; H01L 2224/40475; H01L 2224/84815

(57) ABSTRACT

A semiconductor module includes a lead including a first bonding portion and a coupling portion extending in a Y direction from the first bonding portion. The first bonding portion has a first width end, and a second width end connected to the coupling portion. The lead has first and second length sides opposite to each other in an X direction. The lead has in the X direction first and second widths at first and second positions, and the second position is away from the first position in the Y direction. In the plan view, the lead has a shape in which the first width is greater than the second width such that positions of the first and second length sides at the second position are respectively located inward in the X direction with respect to positions of the first and second length sides at the first position.

### CROSS-REFERENCE TO RELATED APPLICATION

This application is based upon and claims the benefit of priority to Japanese Patent Application No. 2022-171969, Filed on Oct. 27, 2022, the entire contents of which are incorporated herein by reference.

### FIELD

The present invention is related to a semiconductor module, a method for manufacturing a semiconductor module, a semiconductor device, and a vehicle.

### BACKGROUND

Some power conversion devices such as an inverter device include a semiconductor device including a circuit board on which a semiconductor element such as an Insulated Gate Bipolar Transistor (IGBT), a power Metal Oxide Semiconductor Field Effect Transistor (MOSFET), or a Free Wheeling Diode (FWD) is mounted (See, for example, JP 2003-332393 A).

In this type of semiconductor device, a conductive plate sometimes referred to as a lead frame may be used as a conductive member through which a large current flows of conductive members electrically connecting an electrode of the semiconductor element and an external terminal to each other. For example, JP 2003-332393 A describes a semiconductor device in which a source electrode of a semiconductor element mounted on an island including a drain terminal and a post including a source terminal are electrically connected to each other by the conductive plate. For example, WO 2020/071102 A describes a semiconductor device in which a circuit board on which a semiconductor element is mounted is housed in a resin case provided with an external terminal, and an electrode of the semiconductor element and a wiring pattern on the circuit board electrically connected to the external terminal of the resin case are electrically connected to each other by a lead frame. JP H08-130284 A describes some examples of a shape of the lead frame in the semiconductor device not using the resin case, and JP 7028391 B2 describes some examples of a shape of the lead frame in the semiconductor device using the resin case.

### SUMMARY OF THE INVENTION

Of a manufacturing step of the semiconductor device described above, in a step of electrically connecting the electrode of the semiconductor element and the post or the wiring pattern to each other by a conductor plate plate-shaped solder is disposed on the electrode of the semiconductor element and the post or the wiring pattern, and the conductor plate is placed thereon to heat and melt the plate-shaped solder. In this step, a jig in which a region where the plate-shaped solder and the conductor plate are disposed is opened may be used. However, in such a jig, a portion of the conductor plate corresponding to a coupling portion coupling a connecting portion connected to the electrode of the semiconductor element and a connecting portion connected to the post or the wiring pattern is also opened so that the conductor plate can be detached after being connected to the electrode of the semiconductor element or the like. Thus, a position of the plate-shaped solder disposed using the jig may be shifted to a portion corresponding to the coupling portion of the conductor plate of the opening portion of the jig until the plate-shaped solder is heated and melted in a reflow furnace.

The present invention has been made in view of such a point, and an object of the present invention is to provide a method for manufacturing a semiconductor module capable of reducing bonding failure when a conductive member of a circuit board and a lead are bonded to each other using plate-shaped solder.

A semiconductor module according to one aspect of the present invention includes: a circuit board in which a semiconductor element is mounted on a wiring board; and a lead electrically connected to a conductive member in the circuit board via a bonding material, in which the lead includes a bonding portion bonded to the conductive member by the bonding material and a coupling portion extending from the bonding portion, and a contour in plan view of the bonding portion has a shape in which, at a position distant from a second end portion with a position away from the second end portion on a side opposite to a first end portion at which the coupling portion extends by a predetermined distance in an extending direction of the coupling portion as a boundary, positions of both ends in a width direction orthogonal to the extending direction of the coupling portion are displaced in directions of end portions opposite to each other, respectively, and, a dimension in the width direction changes from a first dimension to a second dimension smaller than the first dimension.

According to the present invention, a method for manufacturing a semiconductor module capable of reducing bonding failure when a conductive member of a circuit board and a lead are bonded to each other using a plate-shaped solder can be provided.

### BRIEF DESCRIPTION OF THE DRAWINGS

FIG. 1 is a top view illustrating an internal configuration example of a semiconductor device according to an embodiment;

FIG. 2 is a side cross sectional view schematically illustrating a configuration of a portion on a right side of an A-A′ line when the semiconductor device in FIG. 1 is cut along the A-A′ line;

FIG. 3 is an enlarged partial top view of a region R in FIG. 1;

FIG. 4 is a left side view of a second lead illustrated in FIG. 3;

FIG. 5 is a plan view for explaining one of features in a contour of the second lead in plan view;

FIG. 6 is a flowchart for explaining the method for manufacturing the semiconductor module according to the embodiment;

FIG. 7 is a top view illustrating an example of a state in which a jig for lead bonding is attached and plate-shaped solder is disposed;

FIG. 8 is a side cross sectional view schematically illustrating a configuration of a portion on a right side of a B-B′ line when the portion illustrated in FIG. 7 is cut along the B-B′ line;

FIG. 9 is a top view illustrating an example of a state in which a lead is further disposed;

FIG. 10 is a partial top view for explaining a conventional example of the jig for lead bonding used in manufacturing the semiconductor module;

FIG. 11 is a partial top view for explaining operational effects of the jig for lead bonding according to the embodiment;

FIG. 12 is a plan view for explaining a first modification of the contour of the lead in plan view;

FIG. 13 is a top view for explaining a first modification of a configuration of an opening in the jig for lead bonding;

FIG. 14 is a plan view for explaining a second modification of the contour of the lead in plan view;

FIG. 15 is a top view for explaining a second modification of the configuration of the opening in the jig for lead bonding;

FIG. 16 is a plan view for explaining a third modification of the contour of the lead in plan view;

FIG. 17 is a top view for explaining a third modification of the configuration of the opening in the jig for lead bonding; and

FIG. 18 is a schematic plan view illustrating an example of a vehicle to which the semiconductor device according to the present invention is applied.

### DESCRIPTION OF EMBODIMENTS

Hereinafter, an embodiment of a semiconductor device according to the present invention will be described in detail with reference to the drawings. X, Y, and Z axes in each drawing to be referred to are illustrated for the purpose of defining a plane and a direction in the illustrated semiconductor device or the like, and the X, Y, and Z axes are orthogonal to each other and form a right-handed coordinate system. In the following description, the X direction may be referred to as a left-right direction, the Y direction may be referred to as a front-rear direction, and the Z direction may be referred to as an up-down direction. A plane including the X axis and the Y axis may be referred to as an XY plane, a plane including the Y axis and the Z axis may be referred to as a YZ plane, and a plane including the Z axis and the X axis may be referred to as a ZX plane. These directions (front-rear, left-right, and up-down directions) and planes are terms used for convenience of description, and a correspondence relationship with the XYZ directions, respectively, may change depending on an attachment posture of the semiconductor device. For example, a heat dissipation surface side (cooler side) of the semiconductor device is referred to as a lower surface side, and the opposite side is referred to as an upper surface side. In the present specification, the term “in plan view” means a case where an upper surface or a lower surface (XY plane) of the semiconductor device or the like is viewed from the Z direction. An aspect ratio and a magnitude relationship between the members in each drawing are merely schematically represented, and do not necessarily coincide with a relationship in a semiconductor device or the like actually manufactured. A case in which the magnitude relationship between the members is exaggerated for convenience of description is also assumed.

The semiconductor device illustrated in the following description is applied to, for example, a power conversion device such as an inverter of an industrial or in-vehicle motor. Thus, in the following description, detailed description of the same or similar configuration, function, operation, and the like as those of the known semiconductor device will be omitted.

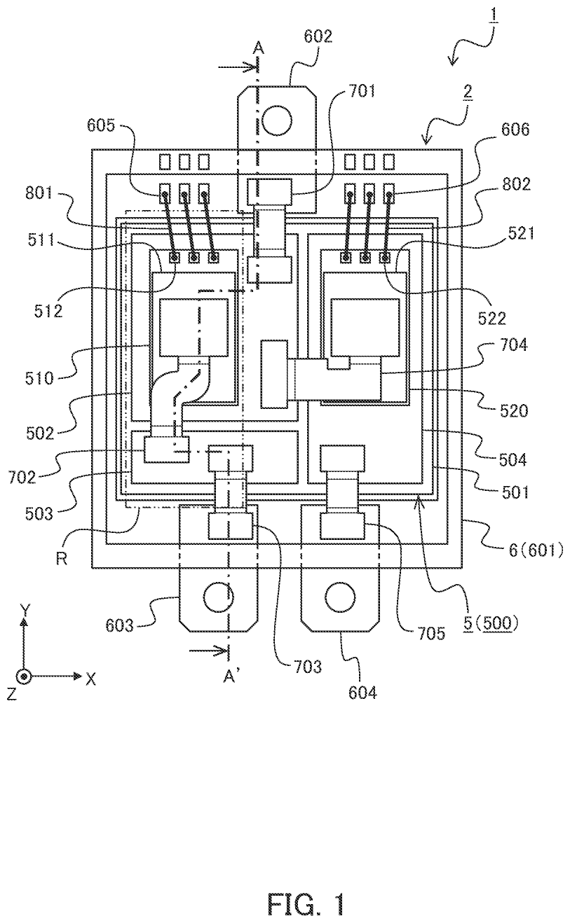

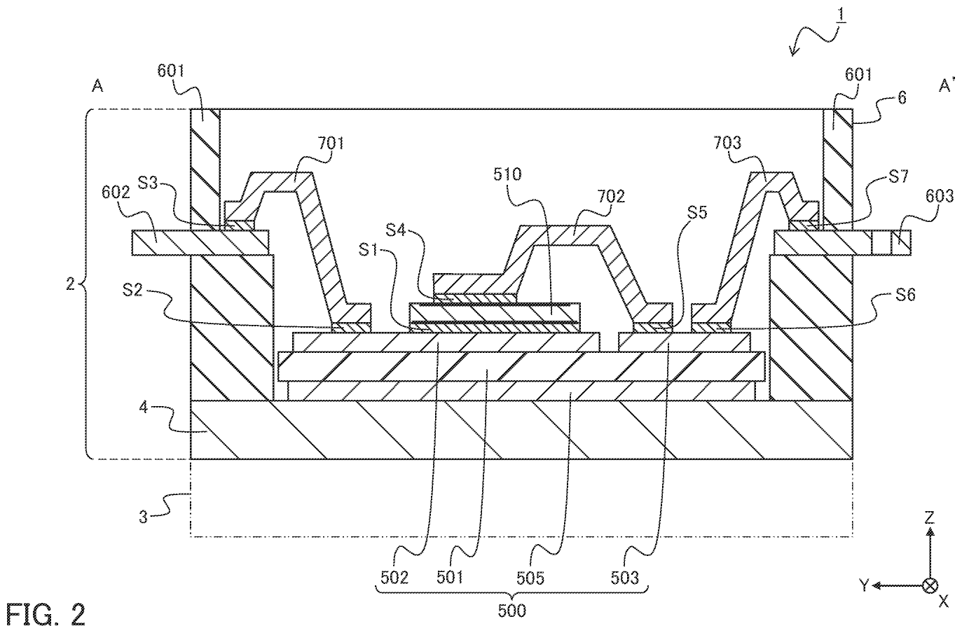

FIG. 1 is a top view illustrating an internal configuration example of a semiconductor device according to an embodiment. FIG. 2 is a side cross sectional view schematically illustrating a configuration of a portion on a right side of an A-A′ line when the semiconductor device in FIG. 1 is cut along the A-A′ line. In FIG. 1, a sealing material filling the case is omitted. In FIG. 2, illustration of the sealing material filling the case, a bonding wire, and the like is omitted.

As illustrated in FIGS. 1 and 2, a semiconductor device 1 according to the present exemplary embodiment is configured by disposing a semiconductor module 2 on an upper surface of a cooler 3. The cooler 3 has an any configuration with respect to the semiconductor module 2.

The cooler 3 releases heat of the semiconductor module 2 to the outside, and has a rectangular parallelepiped shape as a whole. Although not particularly illustrated, the cooler 3 is configured by providing a plurality of fins on a lower surface side of a flat plate-shaped base portion and housing these fins in a water jacket. The cooler 3 is not limited thereto and can be appropriately changed.

The semiconductor module 2 includes a base 4, a circuit board 5, a case 6, leads 701 to 705, bonding wires 801 and 802, and a sealing material (not illustrated).

The base 4 is a substrate on which the circuit board 5 is mounted, and the base 4 on which the circuit board 5 is mounted is attached to a lower surface of the case 6 with the surface on which the circuit board 5 is mounted facing upward. The case 6 includes an insulating member 601 having a rectangular tubular shape (a square ring shape) whose upper surface and lower surface are opened, main terminals 602 to 604 integrated with the insulating member 601, and control terminals 605 and 606. The circuit board 5 mounted on the base 4 is housed in a hollow portion of the insulating member 601 of the case 6. The base 4 is, for example, a metal plate such as a copper plate, and conducts heat generated in the circuit board 5 to the cooler 3. The base 4 may be disposed on the upper surface of the cooler 3 via a thermal conductive material such as thermal grease or thermal compound. In the semiconductor module 2, the base 4 may be omitted, and a conductor pattern 505 (see FIG. 2) of the wiring board 500 included in the circuit board 5 may be in contact with the upper surface of the cooler 3.

The circuit board 5 includes the wiring board 500 and semiconductor elements 510 and 520 mounted on an upper surface of the wiring board 500. The wiring board 500 includes an insulating substrate 501, conductor patterns 502 to 504 provided on an upper surface of the insulating substrate 501, and the conductor pattern 505 provided on a lower surface of the insulating substrate 501. The wiring board 500 may be, for example, a Direct Copper Bonding (DCB) substrate or an Active Metal Brazing (AMB) substrate.

The insulating substrate 501 is not limited to a specific substrate. The insulating substrate 501 may be, for example, a ceramic substrate made of a ceramic material such as aluminum oxide (Al₂O₃), aluminum nitride (AlN), silicon nitride (Si₃N₄), and composite material of aluminum oxide (Al₂O₃) and zirconium oxide (ZrO₂). The insulating substrate 501 may be, for example, a substrate obtained by molding an insulating resin such as an epoxy resin or a substrate obtained by coating a surface of a flat plate-shaped metal core with the insulating resin.

The conductor patterns 502 to 504 provided on the upper surface of the insulating substrate 501 are conductive members used as wiring members in the circuit board 5, and the conductor pattern 505 provided on the lower surface of the insulating substrate 501 is a conductive member used as a heat dissipation member that conducts heat generated in the circuit board 5 to the base 4. These conductor patterns 502 to 505 are made of, for example, a metal plate such as copper or aluminum. The conductor pattern 505 provided on the lower surface of the insulating substrate 501 is bonded to the upper surface of the base 4 via a bonding material (not illustrated) such as solder. The conductor patterns 502 to 504 provided on the upper surface of the insulating substrate 501 may be referred to as conductor layers, conductor plates, or wiring patterns. The conductor pattern 505 provided on the lower surface of the insulating substrate 501 may be referred to as a dissipation layer, a dissipation plate, or a dissipation pattern.

As described above, the conductor patterns 502 to 504 provided on the upper surface of the insulating substrate 501 are the conductive members used as the wiring members in the circuit board 5. In the wiring board 500 illustrated in FIG. 1, the first semiconductor element 510 is mounted on an upper surface of the first conductor pattern 502, and the second semiconductor element 520 is mounted on an upper surface of the third conductor pattern 504.

In the first semiconductor element 510, a first main electrode (not illustrated) provided on a lower surface is bonded to the first conductor pattern 502 by a bonding material S1. The first conductor pattern 502 is electrically connected to the first main terminal 602 provided in the case 6 via the first lead 701. The first lead 701 is bonded to the first conductor pattern 502 by a bonding material S2 and bonded to the first main terminal 602 by a bonding material S3. A second main electrode 511 and a control electrode 512 are provided on the upper surface of the first semiconductor element 510. The second main electrode 511 is electrically connected to the second conductor pattern 503 via the second lead 702. The second lead 702 is bonded to the second main electrode 511 of the first semiconductor element 510 by a bonding material S4 and bonded to the second conductor pattern 503 by a bonding material S5. The control electrode 512 is electrically connected to the control terminal 605 provided on the case 6 by the bonding wire 801.

The second conductor pattern 503 is electrically connected to a second main terminal 603 provided in the case 6 via a third lead 703. The third lead 703 is bonded to the second conductor pattern 503 by a bonding material S6 and bonded to the second main terminal 603 by a bonding material S7.

In the semiconductor device 1 illustrated in FIG. 1, the first conductor pattern 502 is also electrically connected to the second main electrode 521 provided on the upper surface of the second semiconductor element 520 mounted on the third conductor pattern 504 via the fourth lead 704. The fourth lead 704 is bonded to the first conductor pattern 502 and the second main electrode 521 of the second semiconductor element 520 by a bonding material (not illustrated). A control electrode 522 is also provided on the upper surface of the second semiconductor element 520, and the control electrode 522 is electrically connected to the control terminal 606 provided on the case 6 by the bonding wire 802.

The third conductor pattern 504 is electrically connected to a first main electrode provided on a lower surface of second semiconductor element 520 by a bonding material. The third conductor pattern 504 is also electrically connected to the third main terminal 604 provided in the case 6 via the fifth lead 705. The fifth lead 705 is bonded to each of the third conductor pattern 504 and the third main terminal 604 by a bonding material (not illustrated).

In the present embodiment, the first semiconductor element 510 and the second semiconductor element 520 include a Reverse Conducting (RC)-IGBT element in which functions of an Insulated Gate Bipolar Transistor (IGBT) element and a Free Wheeling Diode (FWD) element are integrated.

The semiconductor element mounted on the upper surface of the wiring board 500 is not limited to a specific one. A semiconductor element as a switching element such as the IGBT or the power Metal Oxide Semiconductor Field Effect Transistor (MOSFET) and a semiconductor element as a diode element such as the FWD may be mounted on the upper surface of the wiring board 500. A Reverse Blocking (RB)-IGBT or the like having a sufficient withstand voltage against a reverse bias may be used as the semiconductor element. A shape, a disposition number, a disposition location, and the like of the semiconductor element can be appropriately changed. A layout of the conductor pattern as the wiring member provided on the upper surface side of the wiring board 500 is changed according to a type, the shape, the disposition number, the disposition location, and the like of the semiconductor element to be mounted.

When the first semiconductor element 510 is the IGBT element, the second main electrode 511 on the upper surface side may be referred to as an emitter electrode, and the first main electrode on the lower surface side may be referred to as a collector electrode. When the first semiconductor element 510 is the MOSFET element, the second main electrode 511 on the upper surface side may be referred to as a source electrode, and the first main electrode on the lower surface side may be referred to as a drain electrode. The control electrode provided on the upper surface of first semiconductor element 510 may include a gate electrode and an auxiliary electrode. For example, the auxiliary electrode may be an auxiliary source electrode or an auxiliary emitter electrode electrically connected to the main electrode on the upper surface side and serving as a reference potential with respect to a gate potential. The auxiliary electrode may be a temperature sense electrode electrically connected to a temperature sense unit that may be included in the semiconductor device 1 and measuring the temperature of the semiconductor element. Such an electrode (a main electrode, a gate electrode and an auxiliary electrode) formed on the upper surface of first semiconductor element 510 may be generally referred to as an upper surface electrode.

Each of the first lead 701 to the fifth lead 705 described above is formed by bending a metal plate such as a copper plate, and may be referred to as a lead frame or a metal wiring board.

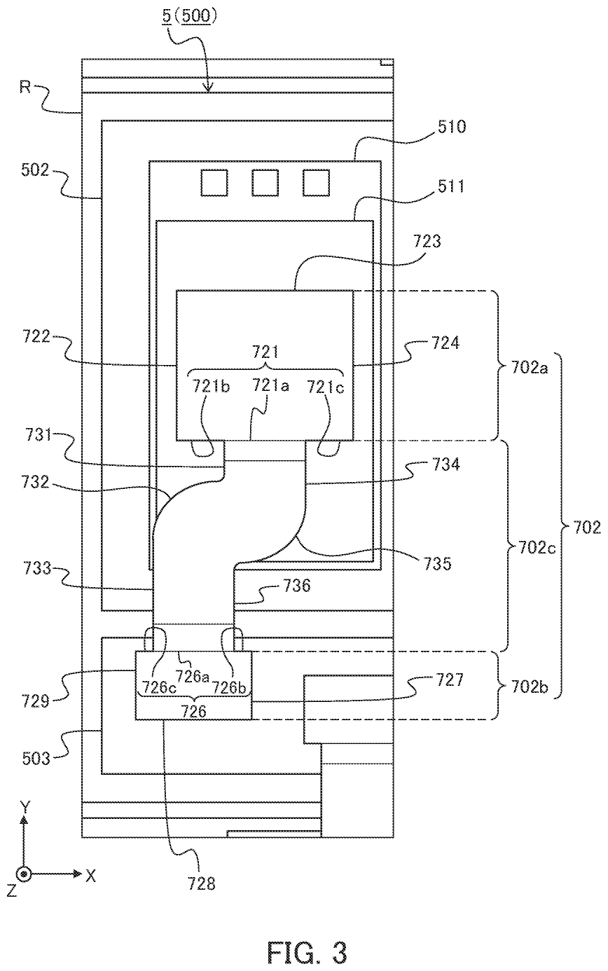

Next, the shape of the lead in the semiconductor device 1 according to the present embodiment will be described with reference to FIGS. 3 to 5. In the following description with reference to FIGS. 3 to 5, the second lead 702 is taken as an example, but the same applies to the other first lead 701 and the third lead 703 to the fifth lead 705.

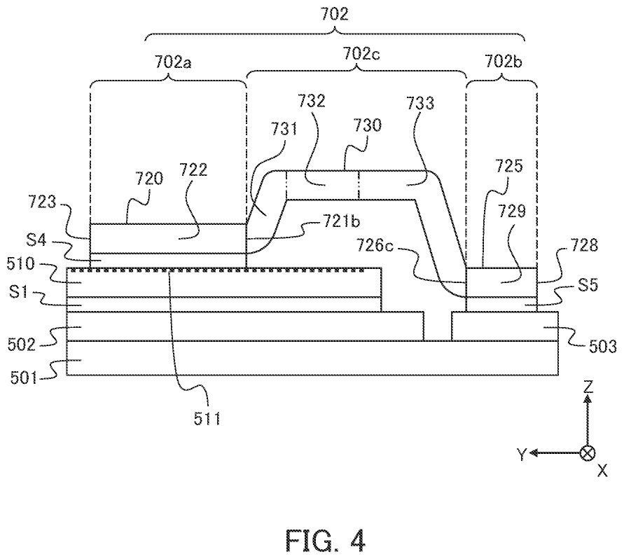

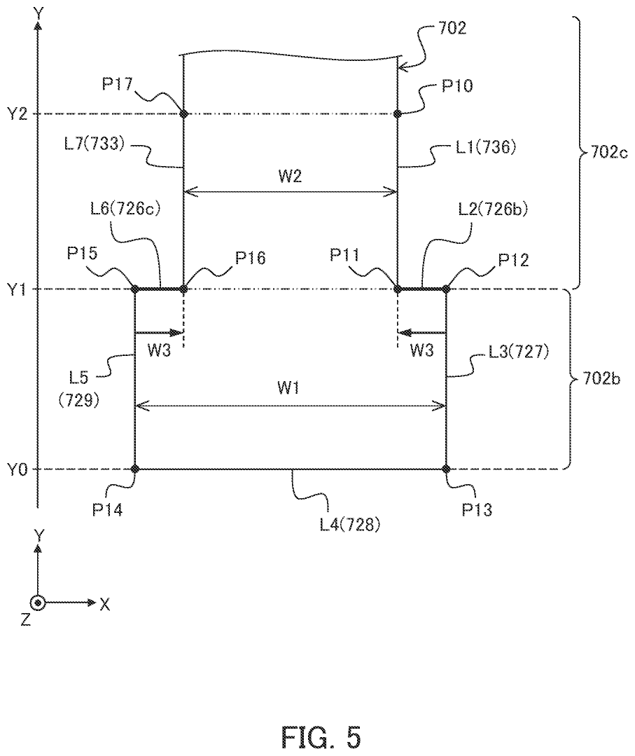

FIG. 3 is an enlarged partial top view of a region R in FIG. 1. FIG. 4 is a left side view of the second lead illustrated in FIG. 3. FIG. 5 is a plan view for explaining one of features in a contour of the second lead in plan view.

As illustrated in FIGS. 3 and 4, the second lead 702 includes a first bonding portion 702a bonded to the second main electrode 511 of the first semiconductor element 510, a second bonding portion 702b bonded to the second conductor pattern 503, and a coupling portion 702c coupling the first bonding portion 702a and the second bonding portion 702b. The coupling portion 702c is bent such that a positional relationship in the up-down direction (Z direction) between the lower surface of the first bonding portion 702a and the lower surface of the second bonding portion 702b corresponds to a positional relationship in the up-down direction between the upper surface of the second main electrode 511 of the first semiconductor element 510 and the upper surface of the second conductor pattern 503 (see FIG. 4).

The first bonding portion 702a in the second lead 702 is a substantially rectangular parallelepiped shaped portion including an upper surface 720 and a lower surface (not illustrated) having a rectangular shape in plan view and four side surfaces 721 to 724 each connected to a respective one of sides parallel to each other of the upper surface 720 and the lower surface. One end of the coupling portion 702c is connected to the side surface 721 of the first bonding portion 702a so as to divide one side surface 721 of the four side surfaces 721 to 724 in the first bonding portion 702a into three sections of a first section 721a, a second section 721b, and a third section 721c. The first section 721a is a section in which the first bonding portion 702a and the coupling portion 702c are connected to each other and serves as a boundary therebetween. The second section 721b is a section located between the first section 721a and one side surface 722 connected to the side surface 721. The third section 721c is a section located between the first section 721a and the other side surface 724 connected to the side surface 721. The second section 721b and the third section 721c of the side surface 721 face a direction opposite to the side surface 723 opposite to the side surface 721. In the direction illustrated in FIG. 3, the second section 721b and the third section 721c of the side surface 721 are surfaces facing the negative side in the Y direction, and the side surface 723 is a surface facing the positive side in the Y direction.

The second bonding portion 702b in the second lead 702 is a substantially rectangular parallelepiped shaped portion including an upper surface 725 and a lower surface (not illustrated) having a rectangular shape in plan view and four side surfaces 726 to 729 each connected to a respective one of sides parallel to each other of the upper surface 725 and the lower surface. The other end of the coupling portion 702c is connected to the side surface 726 of the second bonding portion 702b so as to divide one side surface 726 of the four side surfaces 726 to 729 in the second bonding portion 702b into three sections of a first section 726a, a second section 726b, and a third section 726c. The first section 726a is a section in which the second bonding portion 702b and the coupling portion 702c are connected to each other and serves as a boundary therebetween. The second section 726b is a section located between the first section 726a and one side surface 727 connected to the side surface 726. The third section 726c is a section located between the first section 726a and the other side surface 729 connected to the side surface 726. The second section 726b and the third section 726c of the side surface 726 face a direction opposite to the side surface 728 opposite to the side surface 726. In the direction illustrated in FIG. 3, the second section 726b and the third section 726c of the side surface 726 are surfaces facing the positive side in the Y direction, and the side surface 728 is a surface facing the negative side in the Y direction.

The coupling portion 702c in the second lead 702 is a deformed portion including an upper surface 730 connected to the upper surface 720 of the first bonding portion 702a and the upper surface 725 of the second bonding portion 702b, a lower surface (not illustrated) connected to the lower surface of the first bonding portion 702a and the lower surface of the second bonding portion 702b, and side surfaces 731 to 736 connected to the upper surface 730 and the lower surface. As illustrated in FIG. 3, in the coupling portion 702c of the second lead 702 illustrated in FIG. 3, the shape of the upper surface 730 in plan view includes a rectangular site on each of one end side connected to the first bonding portion 702a and the other end side connected to the second bonding portion 702b, and these rectangular sites are shifted to each other in the X direction.

Reference is now made further to FIG. 5. FIG. 5 illustrates a contour in plan view of the second bonding portion 702b in the second lead 702 and the rectangular site of the coupling portion 702c on the second bonding portion 702b side. In FIG. 5, a reference sign in parentheses after each of reference signs L1 to L7 represents a respective one of reference signs of the side surface of the second bonding portion 702b and the coupling portion 702c illustrated in FIG. 3. As illustrated in FIG. 5, the second lead 702 has a first length side and a second length side opposite to each other in the X direction (second direction), and the first length side includes the sides L1, L2 and L3, and the second length side includes the sides L7, L6 and L5. The second bonding portion 702b has a first width end (L4) and a second width end (an end including sides L2 and L6) in the X direction that are opposite to each other in the Y direction (first direction). A position in the Y direction of a side L4 corresponding to the side surface 728 opposite to the side surface 726 to which the coupling portion 702c of the second bonding portion 702b is connected is defined as Y0, and a position in the Y direction of sides L2 and L3 corresponding to the second section 726b and the third section 726c, respectively, of the side surface 726 to which the coupling portion 702c is connected is defined as Y1. A position on the coupling portion 702c, which is farther than the side surface 726 in the Y direction as viewed from the side surface 728 represented by the side L4 and has the same width W2 as the boundary between the second bonding portion 702b and the coupling portion 702c, is defined as Y2. At this time, a portion where a position in the Y direction in the contour of the second lead 702 in plan view (hereinafter referred to as “contour of the second lead 702”) is within the range from Y0 to Y2 has a shape obtained by combining two rectangles represented by eight points from a point P10 to a point P17. In a range where the position in the Y direction in the contour of the second lead 702 illustrated in FIG. 5 is from Y0 to Y1, a distance (first width) W1 between a side L3 on one end side and a side L5 on the other end side in the X direction parallel to a distance (second width) W2 between one side L1 and the other side L7 of the coupling portion 702c extending from the second bonding portion 702b is larger than the width W2 of the coupling portion 702c. In a range where the position in the Y direction in the contour of the second lead 702 in plan view is from Y1 to Y2, the positions of the one side L1 and the other side L7 in the width direction (X direction) are displaced toward the center side in the width direction from the positions of the one side L3 and the other side L5, respectively, in the second bonding portion 702b. Thus, a portion representing the second bonding portion 702b in the contour of the second lead 702 includes the side L2 connecting the side L3 of the second bonding portion 702b and the side L1 of the coupling portion 702c to each other, and a side L6 connecting the side L5 of the second bonding portion 702b and a side L7 of the coupling portion 702c to each other. These sides L2 and L6 represent the second section 726b and the third section 726c, respectively, in the side surface 726 of the second bonding portion 702b described above with reference to FIG. 3.

As described above, in the second lead 702 of the semiconductor device 1 (semiconductor module 2) of the present embodiment, the positions of both ends in the width direction of the coupling portion 702c orthogonal to the extending direction are displaced in the directions of end portions opposite to each other, respectively, and thus, of the contour in plan view, a contour indicating the second bonding portion 702b and a portion of the coupling portion 702c extending from the second bonding portion 702b changes from the first dimension (W1) to the second dimension (W2) having a dimension in the width direction smaller than the first dimension at a position (for example, a position Y1 in the Y direction in FIG. 5) separated by a predetermined distance in the direction extending from the side L4 on the opposite side to the extending direction of the coupling portion 702c in the second bonding portion 702b. In other words, in the plan view, the second lead 702 has a shape in which the first dimension (W1) at a first position (Y0≤first position<Y1) is greater than the second dimension (W2) at a second position Y1 such that positions of the first and second length sides at the second position Y1, i.e., P11, P16, are respectively located inward in the X direction with respect to positions of the first and second length sides at the first position Y0, for example, i.e., P13, P14.

Although detailed description is omitted, a contour indicating the first bonding portion 702a and a portion of the coupling portion 702c extending from the first bonding portion 702a in the contour of the second lead 702 has the same shape as the contour indicating the second bonding portion 702b and the portion of the coupling portion 702c extending from the second bonding portion 702b described above with reference to FIG. 5 (see FIG. 3). Although detailed description is omitted, a contour indicating the bonding portion and a portion of the coupling portion extending from the bonding portion in the contour in plan view of each lead of the first lead 701 and the third lead 703 to the fifth lead 705, has the same shape as the contour indicating the second bonding portion 702b and the portion of the coupling portion 702c extending from the second bonding portion 702b described above with reference to FIG. 5.

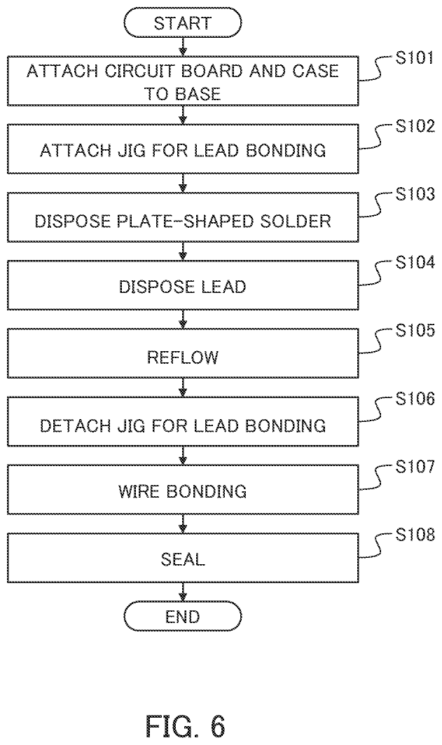

Before describing advantages (operational effects) of using the first lead 701 to the fifth lead 705 having the contour in plan view described above, first, a typical example of a method for manufacturing the semiconductor module 2 according to the present embodiment will be described with reference to FIG. 6.

FIG. 6 is a flowchart for explaining the method for manufacturing the semiconductor module according to the embodiment.

In the manufacturing of the semiconductor module 2, first, the circuit board 5 and the case 6 are attached to the base 4 (step S101). Step S101 may be performed by a known procedure.

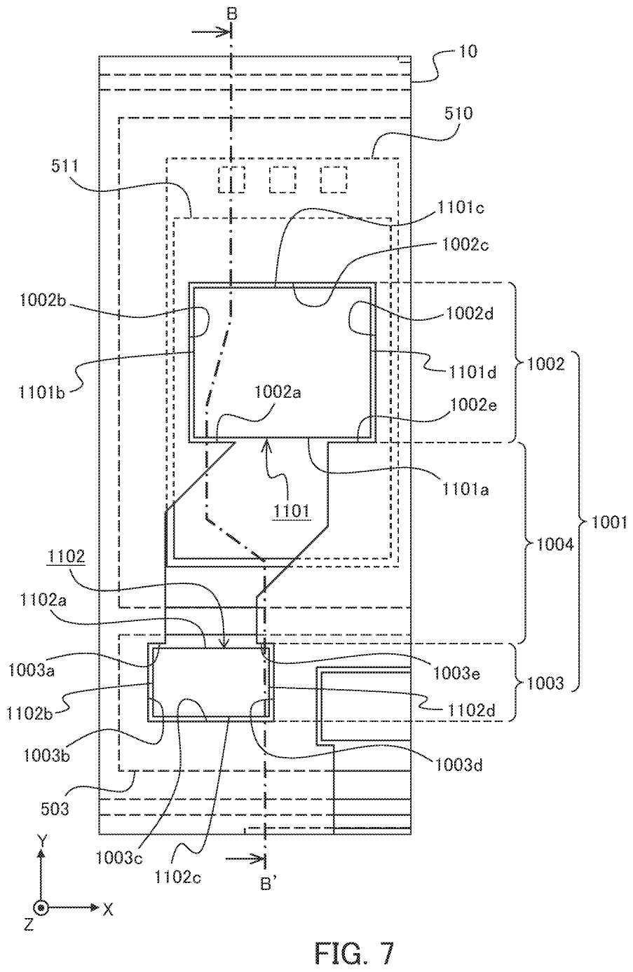

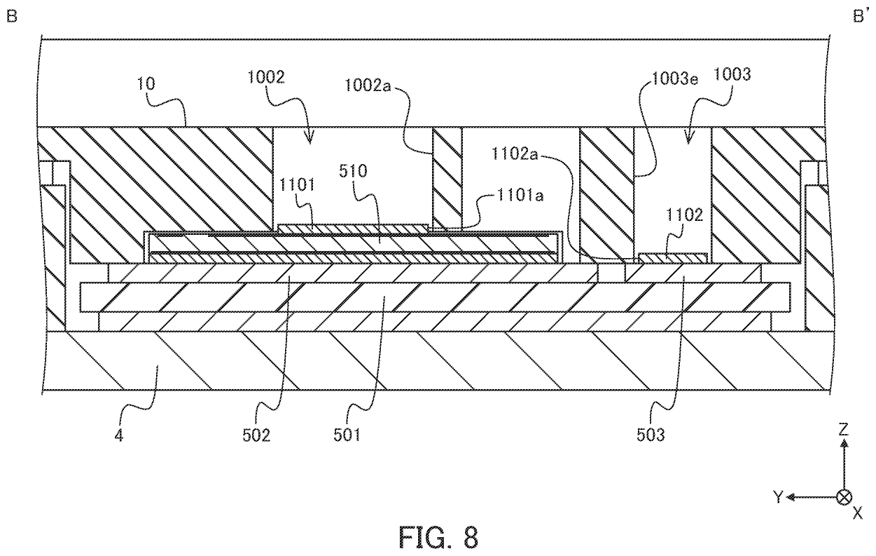

Next, a jig for lead bonding is attached to the base 4 to which the circuit board 5 and the case 6 are attached (step S102). A configuration example of the jig to be attached in step S102 will be described later with reference to FIGS. 7 and 8. The work itself of attaching the jig is performed by a known procedure. Step S102 may be referred to as an installing step of installing the jig on the circuit board 5.

Next, in a state where the jig is attached, the plate-shaped solder used for bonding the lead is disposed (step S103), and the lead is subsequently disposed (step S104). Thereafter, the plate-shaped solder is heated and melted, and reflow is performed to bond the bonding portion of each lead to a conductive member serving as a predetermined bonding target (step S105). By performing the reflow, for example, in the second lead 702, the first bonding portion 702a is bonded to the second main electrode 511 of the first semiconductor element 510, and the second bonding portion 702b is bonded to the second conductor pattern 503. Steps S103 and S104 may be referred to as a disposing step of disposing a plate-shaped bonding material and further disposing the lead. Step S105 may be referred to as a bonding step of bonding the conductive member (the electrode of the semiconductor element, the conductor pattern of the wiring board, and the like) in the circuit board 5 and the lead to each other.

After the reflow, the jig for lead bonding is detached from the base 4 to which the circuit board 5 and the case 6 are attached (step S106), wire bonding (step S107) and sealing (step S108) are performed to obtain the semiconductor module 2 described above. In step S107, the control electrode 512 on the upper surface of first semiconductor element 510 and the control terminal 605 of the case 6 are connected to each other by the bonding wire 801, and the control electrode 522 on the upper surface of the second semiconductor element 520 and the control terminal 606 of the case 6 are connected to each other by the bonding wire 802. In step S108, the hollow portion of the case 6 is filled with a sealing material such as an insulating resin and the sealing material is cured to seal the circuit board 5, the leads 701 to 705, the bonding wires 801 and 802, and the like housed in the case 6. Step S106 may be referred to as a detaching step of detaching the jig from the circuit board. Step S107 may be referred to as a wire bonding step or a bonding step. Step S108 may be referred to as a sealing step.

When the semiconductor module 2 (semiconductor device 1) in which the base 4 is omitted is manufactured, for example, the circuit board 5 and the case 6 are attached to the upper surface of the cooler 3 instead of the base 4.

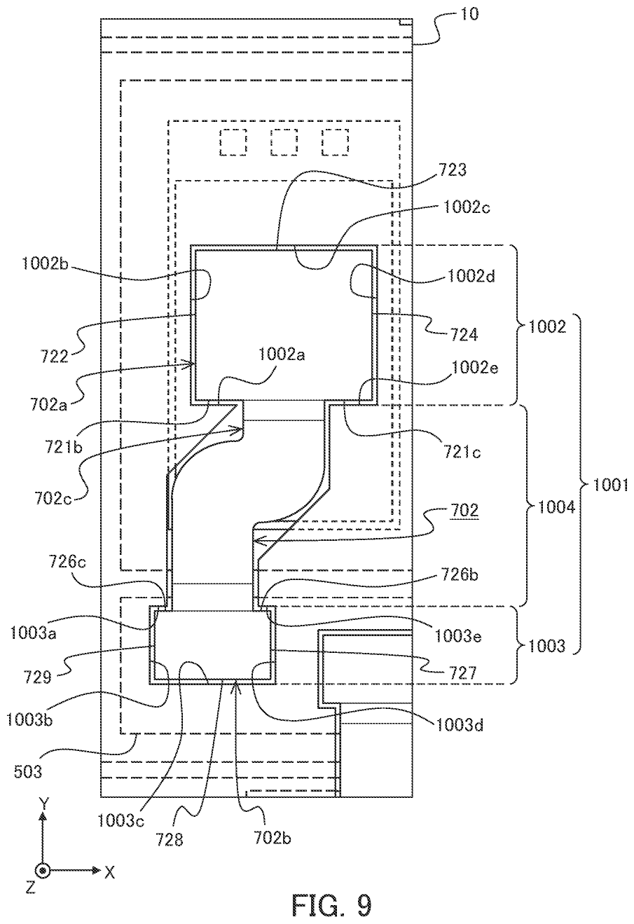

FIG. 7 is a top view illustrating an example of a state in which the jig for lead bonding is attached and the plate-shaped solder is disposed. FIG. 8 is a side cross sectional view schematically illustrating a configuration of a portion on a right side of a B-B′ line when the portion illustrated in FIG. 7 is cut along the B-B′ line. FIG. 9 is a top view illustrating an example of a state in which the lead is further disposed. In FIGS. 7 and 9, a partial region corresponding to the region R in FIG. 1 is enlarged and illustrated.

In the method for manufacturing the semiconductor module 2 described above with reference to FIG. 6, after each lead is bonded to the conductive member serving as the bonding target in step S105, the jig for lead bonding is detached (step S106). Thus, in the jig for lead bonding used for manufacturing the semiconductor module 2 according to the present embodiment, one opening including each portion of the first bonding portion, the second bonding portion, and the coupling portion of the lead in plan view is formed in a region where each lead is disposed. For example, in the region where the second lead 702 is disposed in the jig for lead bonding, one opening including the entire contour of the second lead 702 in plan view illustrated in FIG. 3 is formed.

FIGS. 7 and 8 illustrate an opening 1001 formed in a portion where the second lead 702 is disposed in a jig 10 for lead bonding. The opening 1001 includes a first partial opening 1002 in which a first plate-shaped solder 1101 is disposed, a second partial opening 1003 in which a second plate-shaped solder 1102 is disposed, and a third partial opening 1004 that allows the first partial opening 1002 and the second partial opening 1003 to communicate with each other.

The first plate-shaped solder 1101 having a rectangular shape in plan view corresponding to the first bonding portion 702a of the second lead 702 is disposed in the first partial opening 1002. At this time, the first partial opening 1002 has a rectangular shape in plan view corresponding to the first plate-shaped solder 1101, and wall surfaces 1002b to 1002d represented by three sides, respectively, excluding a side communicating with the third partial opening 1004 in plan view (a side on the negative side in the Y direction of a pair of sides extending in the X direction) face side surfaces 1101b to 1101d, respectively, of the first plate-shaped solder 1101. The first partial opening 1002 includes a wall surface 1002a facing a portion on one end side and a wall surface 1002e facing a portion on the other end side of a side representing the side surface 1101a in plan view of the side surface 1101a facing the third partial opening 1004 side in the first plate-shaped solder 1101 disposed in the first partial opening 1002. That is, the first partial opening 1002 in the jig 10 according to the present embodiment includes two wall surfaces 1002a and 1002e that are separated by a boundary with the third partial opening 1004 in plan view and face the side surface 1101a facing the third partial opening 1004 side in the first plate-shaped solder 1101.

The second plate-shaped solder 1102 having a rectangular shape in plan view corresponding to the second bonding portion 702b of the second lead 702 is disposed in the second partial opening 1003. At this time, the second partial opening 1003 has a rectangular shape in plan view corresponding to the second plate-shaped solder 1102, and wall surfaces 1003b to 1003d represented by three sides, respectively, excluding a side communicating with the third partial opening 1004 in plan view (a side on the positive side in the Y direction of the pair of sides extending in the X direction) face side surfaces 1102b to 1102d, respectively, of the second plate-shaped solder 1102. The second partial opening 1003 includes a wall surface 1003a facing a portion on one end side and a wall surface 1003e facing a portion on the other end side of a side representing the side surface 1102a in plan view of the side surface 1102a facing the third partial opening 1004 side in the second plate-shaped solder 1102 disposed in the second partial opening 1003. That is, the second partial opening 1003 in the jig 10 according to the present embodiment includes two wall surfaces 1003a and 1003e that are separated by a boundary with the third partial opening 1004 in plan view and face the side surface 1102a facing the third partial opening 1004 side in the second plate-shaped solder 1102.

As illustrated in FIG. 9, in the third partial opening 1004 in the opening 1001 of the jig 10, a distance between the two wall surfaces 1002a and 1002e in the first partial opening 1002 separated by the third partial opening 1004 is larger than a width of a connection end in the coupling portion 702c of the second lead 702 with the first bonding portion 702a. Similarly, in the third partial opening 1004, a distance between the two wall surfaces 1003a and 1003e in the second partial opening 1003 separated by the third partial opening 1004 is larger than a width of a connection end in the coupling portion 702c of the second lead 702 with the second bonding portion 702b. As a result, the jig 10 can be easily detached after the second lead 702 is bonded to the second main electrode 511 of the semiconductor element 510 and the second conductor pattern 503.

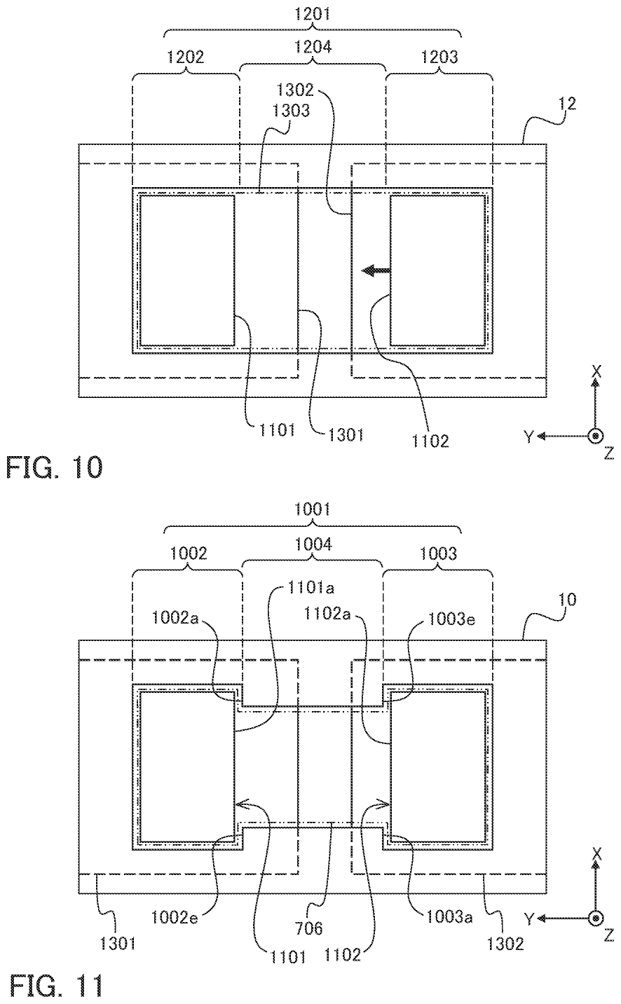

Advantages of manufacturing the semiconductor module 2 by using such a jig 10 will be described below with reference to FIGS. 10 and 11.

FIG. 10 is a partial top view for explaining a conventional example of the jig for lead bonding used in manufacturing the semiconductor module. FIG. 11 is a partial top view for explaining operational effects of the jig for lead bonding according to the embodiment.

In the jig 12 for lead bonding illustrated in FIG. 10 as a conventional example, one opening 1201 has a rectangular shape in plan view in which a lead 1303 connecting a first conductor pattern 1301 and a second conductor pattern 1302 to each other is disposed. That is, in one opening 1201 in the jig 12 illustrated in FIG. 10, a first partial opening 1202 in which the first plate-shaped solder 1101 is disposed, a second partial opening 1203 in which the second plate-shaped solder 1102 is disposed, and a third partial opening 1204 that allows these partial openings to communicate with each other have the same dimension (width) in the X direction. In other words, in one opening 1201 in the jig 12 illustrated in FIG. 10, there is no site that prevents the first plate-shaped solder 1101 disposed in the first partial opening 1202 and the second plate-shaped solder 1102 disposed in the second partial opening 1203 from moving into the third partial opening 1204. Thus, after the first plate-shaped solder 1101 and the second plate-shaped solder 1102 are disposed in the first partial opening 1202 and the second partial opening 1203, respectively, in one opening 1201, the positions of the first plate-shaped solder 1101 and the second plate-shaped solder 1102 may be shifted. For example, when the wiring board 500 of the circuit board 5 is largely warped, the positions of the plate-shaped solders 1101 and 1102 are shifted due to vibration or the like generated at the time of conveyance after disposition. Thus, in the jig 12 illustrated in FIG. 10, a shift amount of the position of one or both of the first plate-shaped solder 1101 and the second plate-shaped solder 1102 at the start of the reflow (step S105 in FIG. 6) may increase, and the bonding area between the bonding portion of the lead 1303 and the first conductor pattern 1301 and the bonding area between the bonding portion of the lead 1303 and the second conductor pattern 1302 may decrease. In addition, when the shift amount further increases, molten solder flows out into a gap between the first conductor pattern 1301 and the second conductor pattern 1302, and insulation properties between the first conductor pattern 1301 and the second conductor pattern 1302 may decrease.

On the other hand, one opening 1001 in the jig 10 for lead bonding used in the present embodiment is formed such that the contour in plan view corresponds to the contour of the lead disposed in the opening 1001 and includes the contour of the lead. For example, the opening 1001 in which the lead 706 is disposed in the jig 10 illustrated in FIG. 11 is provided with the two wall surfaces 1002a and 1002e separated by the third partial opening 1004 and facing the side surface 1101a in the first plate-shaped solder 1101 facing the third partial opening 1004 side, at an end portion in the first partial opening 1002 on a boundary side with the third partial opening 1004. Thus, when an external force for moving the first plate-shaped solder 1101 disposed in the first partial opening 1002 in the direction of the third partial opening 1004 is applied, both end portions of the side surface 1101a abut on the wall surfaces 1002a and 1002e, respectively, of the first partial opening 1002, so that the first plate-shaped solder 1101 is prevented from moving to the third partial opening 1004.

In the jig 10 for lead bonding used in the present embodiment, the contour in plan view of the opening in which the lead is disposed is made to correspond to the shape in plan view of the lead described above with reference to FIGS. 3 to 5, so that an opening dimension of a boundary between the first partial opening 1002 in which the first plate-shaped solder 1101 is disposed and the third partial opening 1004 communicating with the first partial opening 1002 can be made smaller than a dimension of a surface facing the third partial opening 1004 in the first plate-shaped solder 1101 disposed in the first partial opening 1002. As a result, even when an external force in the direction toward the third partial opening 1004 is applied to the first plate-shaped solder 1101 disposed in the first partial opening 1002, the wall surfaces 1002a and 1002e of the first partial opening 1002 can prevent the movement in the direction of the third partial opening 1004, and a movable range of the first plate-shaped solder 1101 disposed in the first partial opening 1002 is restricted.

In the jig 10 for lead bonding used in the present exemplary embodiment, a boundary between the third partial opening 1004 and the second partial opening 1003 in which the second plate-shaped solder 1102 is disposed is also configured similarly to the boundary between the third partial opening 1004 and the first partial opening 1002 in which the first plate-shaped solder 1101 is disposed. Thus, even when an external force in the direction toward the third partial opening 1004 is applied to the second plate-shaped solder 1102 disposed in the second partial opening 1003, the wall surfaces 1003a and 1003e of the second partial opening 1003 can prevent the movement in the direction of the third partial opening 1004, and a movable range of the second plate-shaped solder 1102 disposed in the second partial opening 1003 is restricted.

As described above, by manufacturing the semiconductor module 2 by combining the lead having the contour in plan view described above with reference to FIGS. 3 to 5 and the jig 10 including the opening for disposing the lead described above with reference to FIGS. 7 to 9 and 11, the positional shift of the plate-shaped solder used for bonding the lead and the conductive member (the second main electrode 511 of the semiconductor element 510, the second conductor pattern 503, and the like) on the circuit board 5 can be prevented, and bonding failure, decrease in insulation properties, and the like between the bonding portion of each lead and the conductive member serving as the bonding target can be prevented.

Further, the wall surface of the third partial opening 1004 in one opening 1001 of the jig 10 of the present embodiment is formed so as not to overlap the coupling portion (for example, the coupling portion 702c of the second lead 702 in FIG. 9 and the coupling portion of the lead 706 in FIG. 11) of the lead in plan view. Thus, when the semiconductor module 2 is manufactured according to the procedure illustrated in FIG. 6, the jig 10 can be easily detached after reflow.

The configuration of the jig 10 described above with reference to FIGS. 7 to 9 and 11 is merely an example of the jig 10 that can be used for manufacturing the semiconductor module 2 according to the present embodiment. A contour in plan view of one opening in which one lead in the jig 10 is disposed can be changed according to a contour in plan view of the lead disposed in the opening.

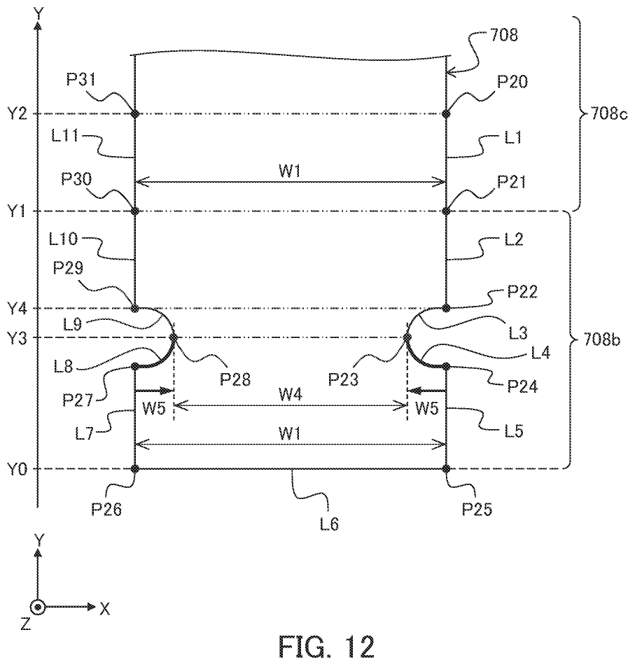

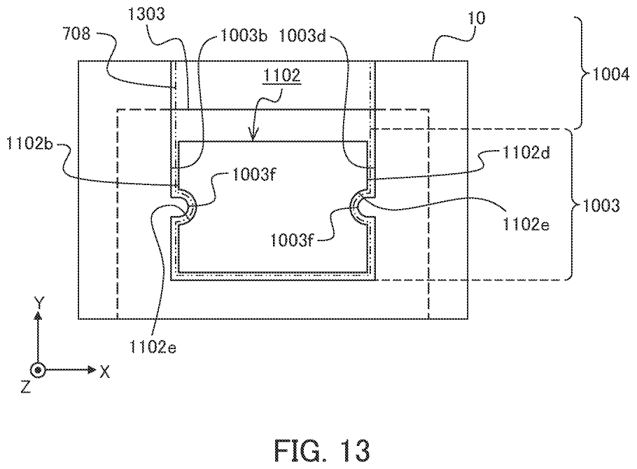

FIG. 12 is a plan view for explaining a first modification of the contour of the lead in plan view. FIG. 13 is a top view for explaining a first modification of the configuration of the opening in the jig for lead bonding; FIG. 12 illustrates a bonding portion 708b bonded to the conductor pattern in the circuit board 5 and only a part of a connection end in a coupling portion 708c with a bonding portion 708b, of an any lead 708 in the semiconductor module. FIG. 13 illustrates the second partial opening 1003 and only a part of the third partial opening 1004, corresponding to the contour of the lead 708 illustrated in FIG. 12 in one opening 1001 of the jig 10 for lead bonding. As shown in FIG. 12, the second lead 708 has the first length side (L1-L5) and the second length side (L7-L11) opposite to each other in the X direction, and the second bonding portion 708b has the first width end (L6) and the second width end (an end at Y1) in the X direction.

In the contour of the lead 708 illustrated in FIG. 12, a boundary between the bonding portion 708b and the coupling portion 708c is at the position Y1 in the Y direction. That is, the contour of the bonding portion 708b in the contour of the lead 708 illustrated in FIG. 12 has a shape having a pair of notches represented by points P21 to P30.

Here, a position in the Y direction of the side L6 of the end portion on the opposite side to a side (that is, the boundary between the bonding portion 708b and the coupling portion 708c indicated by a two-dot chain line connecting the point P21 and the point P30) connected to the coupling portion 708c in the contour of the bonding portion 708b is defined as Y0. Each of the pair of notches is provided on a respective one of sides (a side connecting the point P21 and the point P25 to each other and a side connecting the point P30 and the point P26 to each other) serving as end portions in the width direction (X direction) in the contour of the bonding portion 708b. The notch of the side connecting the point P21 and the point P25 to each other is a concave site represented by arc-shaped trajectories L3 and L4 displaced in a direction of a straight line connecting the point P30 and the point P26 to each other in a section from the point P22 to the point P24 set between a straight line connecting the point P21 and the point P25 to each other. The notch of the side connecting the point P30 and the point P26 to each other is a concave portion represented by arc-shaped trajectories L8 and L9 displaced in a direction of a straight line connecting the point P21 and the point P25 to each other in a section from the point P27 to the point P29 set between a straight line connecting the point P30 and the point P26 to each other.

In the contour of the bonding portion 708b illustrated in FIG. 12, a dimension in the width direction (X direction) of a section from the side L6 opposite to the side connected to the coupling portion 708c to a position in the Y direction of a line connecting the end portions (the point P24 and the point P27) of notches to each other on the side L6 side is W1, and a dimension in the width direction at a position in the Y direction of a line connecting the innermost positions (the point P23 and the point P28) of notches to each other is W4 smaller than W1. That is, the contour of the bonding portion 708b illustrated in FIG. 12 has a shape in which at a position in a direction in which the distance from the side L6 becomes longer with a position (the position of the line connecting the point P24 and the point P27 in FIG. 12 to each other) away from a predetermined distance in the extending direction (the positive side in the Y direction) of the coupling portion 708c from the side L6 on the opposite side to the side connected to the coupling portion 708c as a boundary, positions of both ends in the width direction are displaced in the directions of the end portions opposite to each other, respectively, and the dimension in the width direction changes from a first dimension (W1) to a second dimension (W4) smaller than the first dimension. In other words, in the plan view, the second lead 708 has a shape in which the first dimension (W1) at a first position (Y0<the first position<Y position including P24 and P27) is greater than the second dimension (W2) at the second position Y3 such that positions of the first and second length sides at the second position Y3, i.e., P23, P28, are respectively located inward in the X direction with respect to positions of the first and second length sides at the first position, i.e., P25, P26 or P24, P27, for example.

For example, as illustrated in FIG. 13, the jig 10 used for bonding the lead 708 having the pair of notches illustrated in FIG. 12 is formed into a shape having convex portions 1003f corresponding to the trajectories L3 and L4 indicating one notch and L8 and L9 indicating the other notch, respectively, at positions in the Y direction of portions along the end portions in the width direction (X direction) in the contour of the lead 708 and corresponding to the pair of notches, in the contour of the second partial opening 1003 of the opening in which the lead 708 is disposed.

When the contour of the bonding portion 708b of the lead 708 is formed into the shape having the notch described above, as illustrated in FIG. 13, the second plate-shaped solder 1102 used for bonding the bonding portion 708b is formed into a shape having notches 1102e corresponding to the pair of notches of the bonding portion 708b on the side surfaces 1102b and 1102d, respectively, indicating the end sides in the width direction (X direction) in plan view. In this way, when the second plate-shaped solder 1102 is disposed in the second partial opening 1003 in the jig 10, the convex portions 1003f of the jig 10 are fitted into the pair of notches 1102e, respectively, of the second plate-shaped solder 1102. Thus, when an external force for moving the second plate-shaped solder 1102 disposed in the second partial opening 1003 into the third partial opening 1004 communicating with the second partial opening 1003 is applied, the notch 1102e of the second plate-shaped solder 1102 abuts on the convex portion 1003f of the jig 10, and the movement of the second plate-shaped solder 1102 to the third partial opening 1004 is prevented.

In the combination of the lead 708 having the pair of notches illustrated in FIG. 12 and the jig 10 illustrated in FIG. 13, the movement of the second plate-shaped solder 1102 can be prevented without providing the sides L2 and L6 described above with reference to FIG. 5 along the side to which the coupling portion 708c in the contour of the bonding portion 708b is connected. Thus, the movement of the second plate-shaped solder 1102 can be prevented without shortening a length of a connection section between the bonding portion 708b and the coupling portion 708c in plan view (that is, without reducing the connection area between the bonding portion 708b and the coupling portion 708c). Thus, the configuration described above with reference to FIGS. 12 and 13 is advantageous, for example, in a case where the lead 708 is a lead that flows a large current, or in a case where the lead is a lead that is bonded to a main electrode of a semiconductor element that becomes a high temperature during an operation.

A depth W5 (see FIG. 12) of the pair of notches provided in the bonding portion 708b of the lead 708 is not limited to a specific value. The notch is not limited to a shape represented by an arc-shaped trajectory in plan view as illustrated in FIG. 12. Each of the pair of notches may have, for example, a concave shape represented by a triangular or rectangular trajectory in plan view. In the example described above with reference to FIGS. 12 and 13, the concave notch is provided on the bonding portion 708b side of the lead 708, but the present invention is not limited thereto, and a convex portion may be provided on the bonding portion 708b side of the lead 708 and a notch may be provided on the jig 10 side. In that case, the width at Y3 (hereinafter, referred to as W10, not shown in FIG. 12) will be greater than W1. Thus, in the plan view, the second lead 708 has a shape in which the dimension (W10) at the first position Y3 is greater than the dimension (W1) at the second position Y4 such that positions of the first and second length sides at the second position Y4, i.e., P22, P29, are respectively located inward in the X direction with respect to positions of the first and second length sides at the first position Y3.

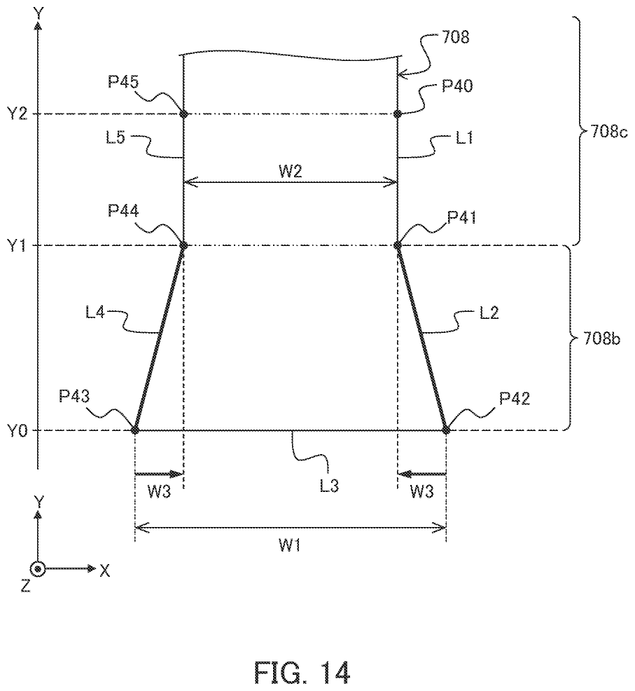

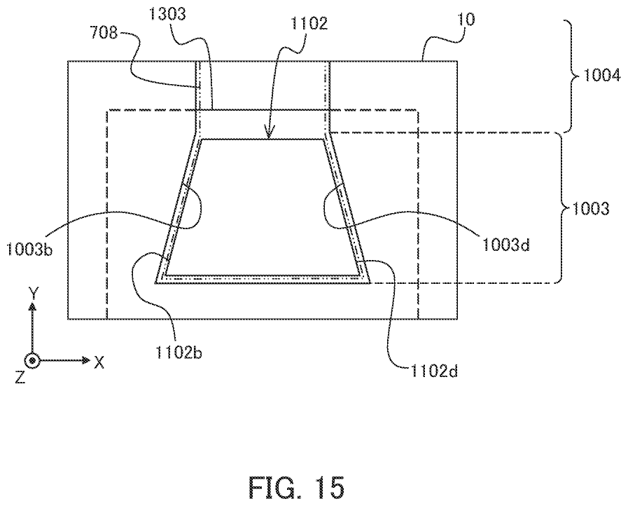

FIG. 14 is a plan view for explaining a second modification of the contour of the lead in plan view. FIG. 15 is a top view for explaining the second modification of the configuration of the opening in the jig for lead bonding. FIG. 14 illustrates the bonding portion 708b bonded to the conductor pattern in the circuit board 5 and only a part of a connection end in the coupling portion 708c with the bonding portion 708b, of an any lead 708 in the semiconductor module. FIG. 15 illustrates the second partial opening 1003 and only a part of the third partial opening 1004, corresponding to the contour of the lead 708 illustrated in FIG. 14 in one opening 1001 of the jig 10 for lead bonding. As shown in FIG. 14, the second lead 708 has the first length side (L1, L2) and the second length side (L4, L5) opposite to each other in the X direction, and the second bonding portion 708b has the first width end (L3) and the second width end (an end at Y1) in the X direction.

In the contour of the lead 708 illustrated in FIG. 14, a boundary between the bonding portion 708b and the coupling portion 708c is at the position Y1 in the Y direction. That is, the contour of the bonding portion 708b in the contour of the lead 708 illustrated in FIG. 14 has a trapezoidal shape represented by points P41 to P44.

Here, a position in the Y direction of the side L3 of the end portion on the opposite side to a side (that is, the boundary between the bonding portion 708b and the coupling portion 708c indicated by a two-dot chain line connecting the point P41 and the point P44) connected to the coupling portion 708c in the contour of the bonding portion 708b is defined as Y0. The contour of the bonding portion 708b is assumed to be an isosceles trapezoid with a boundary between the bonding portion 708b and the coupling portion 708c as an upper base and a side L3 opposite to the boundary as a lower base. In this case, the contour of the bonding portion 708b has a tapered shape in which a width at a position in the Y direction away from the side L3 serving as the lower base by a predetermined distance in the extending direction of the coupling portion 708c is shortened in proportion to a distance from the side L3. That is, the contour of the bonding portion 708b illustrated in FIG. 14 also has a shape in which at a position in a direction in which the distance from the side L3 becomes longer with a position away from a predetermined distance in the extending direction (the positive side in the Y direction) of the coupling portion 708c from the side L3 on the opposite side to the side connected to the coupling portion 708c as a boundary, positions of both ends in the width direction are displaced in the directions of the end portions opposite to each other, respectively, and the dimension in the width direction changes from the first dimension to the second dimension smaller than the first dimension. In other words, in the plan view, the second lead 708 has a shape in which the first dimension (W1) at the first position Y0 is greater than the second dimension (W2) at the second position Y1 such that positions of the first and second length sides at the second position Y1, i.e., P41, P44, are respectively located inward in the X direction with respect to positions of the first and second length sides at the first position Y0, i.e., P42, P43.

In the jig 10 used for bonding the lead 708 including the bonding portion 708b having the isosceles trapezoidal shape in plan view illustrated in FIG. 14, as illustrated in FIG. 15, the contour of the second partial opening 1003 in the opening in which the lead 708 is disposed is formed into the isosceles trapezoid which includes the contour of the bonding portion 708b of the lead 708 and whose dimension in the width direction (X direction) of the boundary between the second partial opening 1003 and the third partial opening 1004 is slightly larger than the width W2 of the coupling portion 708c of the lead 708. In this case, the second plate-shaped solder 1102 disposed in the second partial opening 1003 is formed into an isosceles trapezoid having substantially the same shape as the bonding portion 708b of the lead 708 in plan view. In this way, the side surfaces 1102b and 1102d of the second plate-shaped solder 1102 represented by the oblique sides in the contour of the second plate-shaped solder 1102 face substantially parallel to the wall surfaces 1003b and 1003d represented by the oblique sides in the contour of the second partial opening 1003 of the jig 10. Thus, when the external force for moving the second plate-shaped solder 1102 disposed in the second partial opening 1003 into the third partial opening 1004 communicating with the second partial opening 1003 is applied, the side surfaces 1102b and 1102d of the second plate-shaped solder 1102 abut on the wall surfaces 1003b and 1003d, respectively, of the jig 10, and the movement of the second plate-shaped solder 1102 to the third partial opening 1004 is prevented.

The angle of the oblique side when the contour of the bonding portion 708b of the lead 708 is formed into the isosceles trapezoid is not limited to a specific angle.

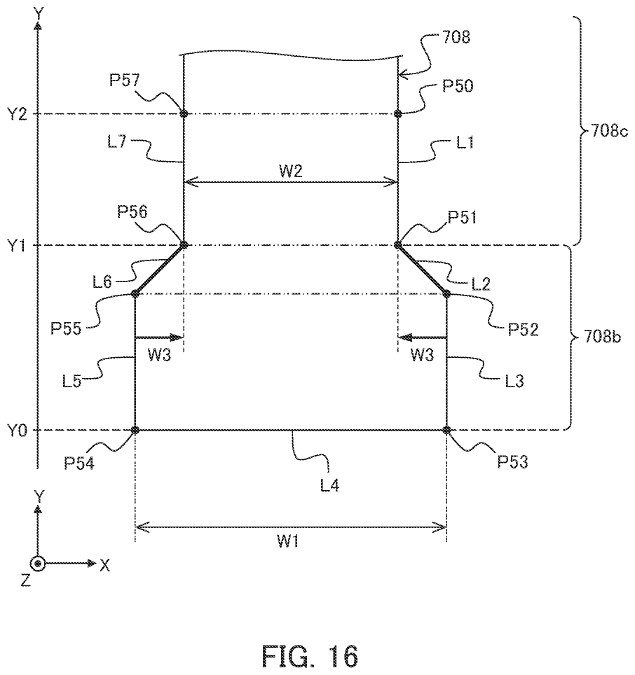

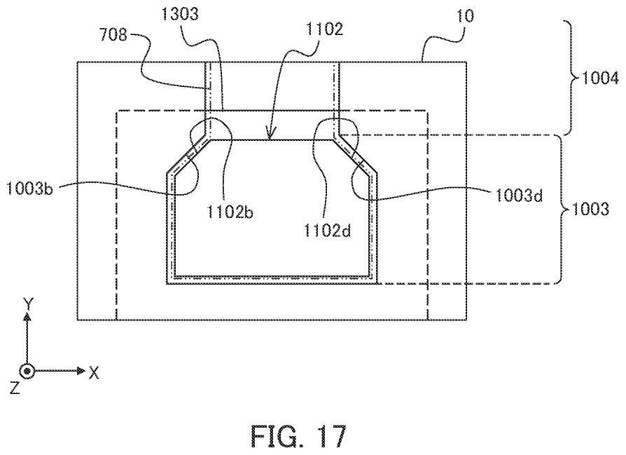

FIG. 16 is a plan view for explaining a third modification of the contour of the lead in plan view. FIG. 17 is a top view for explaining a third modification of the configuration of the opening in the jig for lead bonding. FIG. 16 illustrates the bonding portion 708b bonded to the conductor pattern in the circuit board 5 and only a part of the connection end in the coupling portion 708c with the bonding portion 708b, of an any lead 708 in the semiconductor module. FIG. 17 illustrates the second partial opening 1003 and only a part of the third partial opening 1004, corresponding to the contour of the lead 708 illustrated in FIG. 16 in one opening 1001 of the jig 10 for lead bonding. As shown in FIG. 16, the second lead 708 has the first length side (L1-L3) and the second length side (L5-L7) opposite to each other in the X direction, and the second bonding portion 708b has the first width end (L4) and the second width end (an end at Y1) in the X direction.

In the contour of the lead 708 illustrated in FIG. 16, a boundary between the bonding portion 708b and the coupling portion 708c is at the position Y1 in the Y direction. That is, the contour of the bonding portion 708b in the contour of the lead 708 illustrated in FIG. 16 has a shape obtained by combining an isosceles trapezoid represented by points P51, P52, P55, and P56 and a rectangle represented by points P52, P53, P54, and P55. In other words, in the plan view, the second lead 708 has a shape in which the first dimension (W1) at the first position (Y0<the first position<Y position including P52 and P55) is greater than the second dimension (W2) at the second position Y3 such that positions of the first and second length sides at the second position Y1, i.e., P51, P56, are respectively located inward in the X direction with respect to positions of the first and second length sides at the first position, i.e., P53, P54 or P52, P55, for example.

The jig 10 used for bonding the lead 708 including the bonding portion 708b represented by the contour illustrated in FIG. 16 is formed such that as illustrated in FIG. 17, the contour of the second partial opening 1003 in the opening in which the lead 708 of the jig 10 is disposed includes the contour of the bonding portion 708b of the lead 708, and the dimension in the width direction (X direction) of the boundary between the second partial opening 1003 and the third partial opening 1004 is slightly larger than the width W2 of the coupling portion 708c of the lead 708. In this case, the second plate-shaped solder 1102 disposed in the second partial opening 1003 is formed into a shape obtained by combining an isosceles trapezoid and a rectangle having substantially the same shape as the bonding portion 708b of the lead 708 in plan view. In this way, the side surfaces 1102b and 1102d of the second plate-shaped solder 1102 represented by the oblique sides (oblique sides corresponding to sides L2 and L6 in FIG. 16) in the contour of the second plate-shaped solder 1102 face substantially parallel to the wall surfaces 1003b and 1003d represented by the oblique sides in the contour of the second partial opening 1003 of the jig 10. Thus, when the external force for moving the second plate-shaped solder 1102 disposed in the second partial opening 1003 into the third partial opening 1004 communicating with the second partial opening 1003 is applied, the side surfaces 1102b and 1102d of the second plate-shaped solder 1102 abut on the wall surfaces 1003b and 1003d, respectively, of the jig 10, and the movement of the second plate-shaped solder 1102 to the third partial opening 1004 is prevented.

Furthermore, as illustrated in FIGS. 16 and 17, by setting the section in which the dimension in the width direction (X direction) in the bonding portion 708b changes from the boundary with the coupling portion 708c to a position in the Y direction closer to the boundary than the side L4 on the opposite side of the boundary, an angle of the oblique side can be increased while suppressing the reduction in the bonding area of the bonding portion 708b. Thus, the bonding area between the bonding portion 708b and the conductor pattern can be secured and the movable range of the second plate-shaped solder 1102 to the third partial opening 1004 side can be minimized at the same time. In a case where the two wall surfaces 1003b and 1003d located at the end portion in the width direction (X direction) in the second partial opening 1003 are formed to be tapered as approaching the third partial opening 1004, for example, as illustrated in FIG. 16, when only a part in the second partial opening 1003 close to the third partial opening 1004 is formed to be tapered, a corner portion having an acute angle in plan view can be prevented from being generated in the bonding surface as compared with, for example, the case where the contour in plan view is the isosceles trapezoid illustrated in FIG. 14.

In the modification described above with reference to FIGS. 12 to 17, only the configuration on the second partial opening 1003 side of the jig 10 has been described. However, the configuration on the first partial opening 1002 side may be similar. In the jig 10 according to the present embodiment, the configuration on the first partial opening 1002 side and the configuration on the second partial opening 1003 side in one opening 1001 may be same as or different from each other. For example, in one opening 1001, the second partial opening 1003 side may have the configuration described above with reference to FIG. 5, and the first partial opening 1002 side may have the configuration of any of the modifications described above with reference to FIGS. 12 to 17.

The modifications described above with reference to FIGS. 12 to 17 are merely examples of the configurations for preventing the movement of the plate-shaped solder disposed in the first partial opening and the second partial opening of the jig 10 to the third partial opening. Each of the first partial opening and the second partial opening may have a shape in which the contour in plan view includes a portion that abuts on the side surface of the plate-shaped solder disposed in the partial opening and can prevent movement to the third partial opening. Thus, in the bonding portion of each lead in the semiconductor module 2 according to the present embodiment, the side surface of the bonding portion corresponding to the outer peripheral portion excluding the section coupled to the coupling portion in plan view may have a shape in which, when a side surface (for example, the wall surface of the opening of the jig 10 described above) facing the side surface is present, the side surfaces abut on each other and the movement of the bonding portion in the extending direction of the coupling portion is prevented.

Furthermore, the method for manufacturing the semiconductor module 2 according to the present embodiment may be a method using the jig 10 described above, but not limited to the procedure described above with reference to FIG. 6, and may be performed by other procedures.

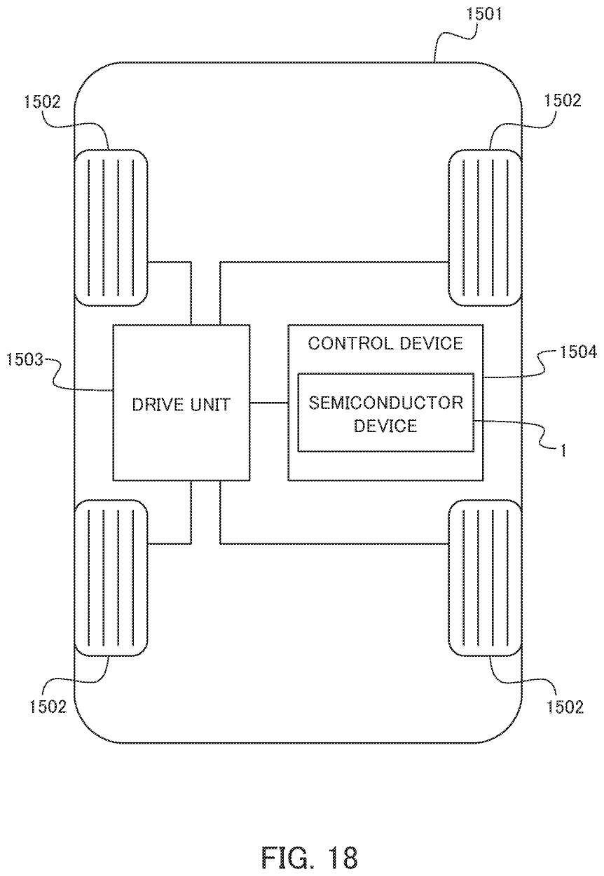

As described above, the semiconductor device 1 including the semiconductor module 2 of the present embodiment can be applied to the power conversion device such as the inverter of the in-vehicle motor. A vehicle to which the semiconductor device 1 of the present invention is applied will be described with reference to FIG. 18.

FIG. 18 is a schematic plan view illustrating an example of the vehicle to which the semiconductor device according to the present invention is applied. A vehicle 1501 illustrated in FIG. 18 includes, for example, a four-wheeled vehicle including four wheels 1502. The vehicle 1501 may be, for example, an electric vehicle that drives wheels by a motor or the like, or a hybrid vehicle using power of an internal combustion engine in addition to the motor.

The vehicle 1501 includes a drive unit 1503 that applies power to the wheels 1502 and a control device 1504 that controls the drive unit 1503. The drive unit 1503 may include, for example, at least one of an engine, the motor, and a hybrid of the engine and the motor.

The control device 1504 performs control (for example, power control) of the drive unit 1503 described above. The control device 1504 includes the semiconductor device 1 described above. The semiconductor device 1 may be configured to perform power control on the drive unit 1503.

By manufacturing the semiconductor module 2 of the semiconductor device 1 used for this type of vehicle 1501 by using the jig 10 described above, bonding failure between the lead and the bonding target, decrease in insulation properties, and the like can be prevented, and a manufacturing yield of the semiconductor module 2 can be improved. Thus, for example, the manufacturing cost of the semiconductor device 1 used for the vehicle 1501 can be reduced.

The vehicle to which the above-described semiconductor device 1 (semiconductor module 2) can be applied is not limited to the four-wheeled vehicle illustrated in FIG. 18, and may be a two-wheeled vehicle or a railroad vehicle.

In the above embodiment, the circuit board 5 (wiring board 500) and the semiconductor elements 510 and 520 are formed in the rectangular shape or the square shape in plan view, but the present invention is not limited to this configuration. These configurations may be formed in a polygonal shape other than the above.

The present embodiment and the modifications have been described, but as another embodiment, the above-described embodiment and the modifications may be wholly or partially combined.

The present embodiment is not limited to the above-described embodiment and modifications, and various changes, substitutions, and modifications may be made without departing from the spirit of the technical idea. When the technical idea can be realized in another manner by the progress of the technology or another derived technology, the technology may be implemented by using the manner. Thus, the claims cover all implementations that may be included within the scope of the technical idea.

The feature points in the above exemplary embodiments will be described below.

A semiconductor module according to the above embodiment includes: a circuit board in which a semiconductor element is mounted on a wiring board; and a lead electrically connected to a conductive member in the circuit board via a bonding material, in which the lead includes a bonding portion bonded to the conductive member by the bonding material and a coupling portion extending from the bonding portion, and a contour in plan view of the bonding portion has a shape in which at a position distant from a second end portion with a position away from the second end portion on a side opposite to a first end portion at which the coupling portion extends by a predetermined distance in an extending direction of the coupling portion as a boundary, positions of both ends in a width direction orthogonal to the extending direction of the coupling portion are displaced in directions of end portions opposite to each other, respectively, and, a dimension in the width direction changes from a first dimension to a second dimension smaller than the first dimension.

In the semiconductor module according to the above embodiment, the bonding portion of the lead has a rectangular shape in which the dimension in the width direction in plan view is larger than a dimension of the coupling portion in the width direction, and the contour in plan view of the bonding portion includes a side that changes from an end portion in the width direction to an end portion of the coupling portion in the width direction.

In the semiconductor module according to the above embodiment, the bonding portion of the lead includes groove portions that change in directions of end portions opposite to each other at the end portions, respectively, in the width direction in the contour in plan view.

In the semiconductor module according to the above embodiment, the bonding portion of the lead includes a portion whose contour in plan view is tapered as approaching the coupling portion.

In the semiconductor module according to the above embodiment, the conductive member of the circuit board includes an electrode of the semiconductor element and a conductor pattern of the wiring board, and the lead includes a first bonding portion bonded to the electrode of the semiconductor element by a first bonding material, a second bonding portion bonded to the conductor pattern of the wiring board by a second bonding material, and the coupling portion coupling the first bonding portion and the second bonding portion to each other.

A method for manufacturing a semiconductor module according to the above embodiment includes a connecting step of electrically connecting a conductive member and a lead in a circuit board in which a semiconductor element is mounted on a wiring board to each other via a bonding material, in which the connecting step includes: an installing step of installing, on the circuit board, a jig in which an opening is formed, the opening including a partial opening corresponding to a bonding portion bonded to the conductive member by the bonding material in the lead and a partial opening corresponding to a coupling portion extending from the bonding portion; a disposing step of disposing a plate-shaped bonding material in the partial opening corresponding to the bonding portion in the installed jig, and further disposing the lead; a bonding step of bonding the conductive member and the bonding portion of the lead to each other by heating and melting the plate-shaped bonding material; and a detaching step of detaching the jig from the circuit board, in the lead, a contour in plan view of the bonding portion has a shape in which at a position distant from a second end portion with a position away from the second end portion on a side opposite to a first end portion at which the coupling portion extends by a predetermined distance in an extending direction of the coupling portion as a boundary, positions of both ends in a width direction orthogonal to the extending direction of the coupling portion are displaced in directions of end portions opposite to each other, respectively, and, a dimension in the width direction changes from a first dimension to a second dimension smaller than the first dimension, and in the partial opening corresponding to the bonding portion in the jig, a contour in plan view has a shape in which a contour of the lead including the bonding portion and the coupling portion are included, and a portion that changes along a trajectory of a portion whose dimension in the width direction changes from the first dimension to the second dimension.

A semiconductor device according to the above embodiment includes the above-described semiconductor module; and a cooler disposed on a surface opposite to a surface on which the semiconductor element of the circuit board of the semiconductor module is mounted.

The vehicle according to the above embodiment includes the above-described semiconductor module or the semiconductor device.

As described above, the present invention has an effect of being capable of reducing bonding failure and decrease in insulation properties when a conductive member of a circuit board and a lead are bonded to each other using a plate-shaped bonding material such as plate-shaped solder, and is particularly useful for a semiconductor module for industrial or electrical equipment, a semiconductor device, and a vehicle.

What is claimed is:

1. A semiconductor module, comprising:
a circuit board includes a first conductive member and a second conductive member disposed thereon and a semiconductor element mounted on the second conductive member; and
a lead electrically connecting the semiconductor element to the first conductive member, wherein
the lead includes a first bonding portion bonded to the first conductive member via a bonding material and a coupling portion extending in a first direction from the first bonding portion, and
the first bonding portion has a first width end and a second width end that is opposite to the first width end and is connected to the coupling portion, and the lead has a first length side and a second length side opposite to each other in a second direction orthogonal to the first direction,
the lead has in the second direction, a first width at a first position and a second width at a second position, the first position being located in the bonding portion, the second position being located away from the first position in the first direction from the first width end toward the second width end, and
in the plan view, the lead has a shape in which the first width is greater than the second width such that positions of the first and second length sides at the second position are respectively located inward in the second direction with respect to positions of the first and second length sides at the first position.

2. The semiconductor module according to claim 1, wherein
the first bonding portion of the lead has a rectangular shape in the plan view, and has the first width in the second direction, and
the coupling portion has the second width in the second direction.

3. The semiconductor module according to claim 1, wherein each of the first length side and the second length side has a groove that is located at the first bonding portion of the lead and is recessed inward in the second direction in the plan view.

4. The semiconductor module according to claim 1, wherein the first bonding portion of the lead includes a tapered portion, and a width in the second direction between the first length side and the second length side at a position in the tapered portion becomes smaller as the position in the tapered portion approaches the coupling portion.

5. The semiconductor module according to claim 1, wherein
the semiconductor element includes an electrode,
the lead further includes a second bonding portion bonded to the electrode of the semiconductor element via a second bonding material, and
the coupling portion couples the first bonding portion and the second bonding portion to each other.

6. A method for manufacturing a semiconductor module, comprising:
preparing a lead having a first bonding portion and a coupling portion extending in a first direction from the first bonding portion, wherein
the first bonding portion has a first width end and a second width end that is opposite to the first width end and is connected to the coupling portion, and the lead has a first length side and a second length side opposite to each other in a second direction orthogonal to the first direction,
the lead has in the second direction a first width at a first position and a second width at a second position, the first position being located in the bonding portion, the second position being located away from the first position in the first direction from the first width end toward the second width end, and
in the plan view, the lead has a shape in which the first width is greater than the second width such that positions of the first and second length sides at the second position are respectively located inward in the second direction with respect to positions of the first and second length sides at the first position;
electrically connecting the lead to the conductive member on a circuit board on which a semiconductor element is mounted via a bonding material, the connecting the lead including:
installing, on the circuit board, a jig having an opening that includes a first opening for the bonding portion and a second opening for the coupling portion;
disposing a plate-shaped bonding material in the first opening of the installed jig, and further disposing the lead in the first opening;
bonding the conductive member and the bonding portion of the lead to each other by heating to melt the plate-shaped bonding material; and
detaching the jig from the circuit board, wherein
the opening of the jig has a size so that the bonding portion and the coupling portion are disposed within the opening and has a shape such that in the plan view, a width of the opening in the second direction changes to follow a change of the first width to the second width of the lead.

7. A semiconductor device, comprising:
the semiconductor module according to claim 1; and
a cooler disposed at a side of the circuit board opposite to a side of the circuit board where the semiconductor element is mounted.

8. A vehicle, comprising the semiconductor module according to claim 7.
